(19) United States
(12) Patent Application Publication
(10) Pub. No.: US 2025/0176236 A1
(43) Pub. Date: May 29, 2025

(54) STRUCTURES WITH DOPED SEMICONDUCTOR LAYERS AND METHODS AND SYSTEMS FOR FORMING SAME

(71) Applicant: ASM IP Holding B.V., Almere (NL)

(72) Inventors: Lucas Petersen Barbosa Lima, Heverlee (BE); Rami Khazaka, Leuven (BE); Qi Xie, Wilsele (BE)

(21) Appl. No.: 19/042,201

(22) Filed: Jan. 31, 2025

Related U.S. Application Data
(63) Continuation of application No. 18/107,688, filed on Feb. 9, 2023, now Pat. No. 12,266,695.
Application No. 18/107,688 is a division of application No. 17/084,354, filed on Oct. 29, 2020, now Pat. No. 11,594,600.
(60) Provisional application No. 62/930,752, filed on Nov. 5, 2019.

(51) Int. Cl. H10D 62/834; H01L 21/02; H01L 21/67

(52) U.S. Cl. CPC H10D 62/834; H01L 21/02579; H01L 21/67063

(57) ABSTRACT

Methods and systems for depositing material, such as doped semiconductor material, are disclosed. An exemplary method includes providing a substrate, forming a first doped semiconductor layer overlying the substrate, and forming a second doped semiconductor layer overlying the first doped semiconductor layer, wherein the first doped semiconductor layer comprises a first dopant and a second dopant, and wherein the second doped semiconductor layer comprises the first dopant. Structures and devices formed using the methods and systems for performing the methods are also disclosed.

### CROSS-REFERENCE TO RELATED APPLICATIONS

This application is a continuation of, and claims priority to, U.S. patent application Ser. No. 18/107,688 filed Feb. 9, 2023 and titled STRUCTURES WITH DOPED SEMICONDUCTOR LAYERS AND METHODS AND SYSTEMS FOR FORMING SAME; which is a divisional of, and claims priority to, U.S. patent application Ser. No. 17/084,354 filed Oct. 29, 2020 and titled STRUCTURES WITH DOPED SEMICONDUCTOR LAYERS AND METHODS AND SYSTEMS FOR FORMING SAME (now U.S. Pat. No. 11,594,600 issued on Feb. 28, 2023); which claims priority to U.S. Provisional Application Ser. No. 62/930,752 filed Nov. 5, 2019 and titled STRUCTURES WITH DOPED SEMICONDUCTOR LAYERS AND METHODS AND SYSTEMS FOR FORMING SAME, the disclosures of which are hereby incorporated by reference in their entirety.

### FIELD OF INVENTION

The present disclosure generally relates to methods and systems suitable for forming electronic device structures. More particularly, the disclosure relates to methods and systems that can be used to form structures including doped semiconductor layers.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

One approach to improve semiconductor device performance is to enhance the carrier mobility, and consequently the transistor drive current, utilizing strain induced effects. For example, it has been shown that the hole mobility may be considerably enhanced in p-channel Group IV semiconductor transistors employing stressor regions, such as stressor regions employed in the source and drain regions of the transistors.

Further, reduction in contact resistance to the active regions of a semiconductor device structure may be desirable for ongoing device improvement at future technology nodes. For example, for CMOS device structures, a contact resistance may include the electrical resistance between a contact structure and one or more active (e.g., stressor) regions, such as source and drain regions of the transistor structure. In the case of an n-type MOS device, the stressor region may comprise a highly doped region, i.e., with a carrier density of approximately 5×10²⁰ cm⁻³ or more, doped with either phosphorus or arsenic. The high doping levels that may be achieved in the n-type MOS device stressor region may result in a contact resistivity below 0.3 mΩ-cm. However, for a p-type MOS device, boron is typically used as a dopant. In some cases, boron may have relatively low solubility in the semiconductor material, and thus high concentrations of the p-type dopant and thus low contact resistance to the semiconductor material can be difficult to obtain.

By way of examples, attempts to lower the contact resistance of silicon germanium films include growing SiGe layers with high boron concentrations. However, high boron concentrations are difficult to achieve with higher Ge:Si ratios due to the low boron solubility in germanium, and therefore, attempts to simply increase the boron concentration in the silicon germanium film have generally not been sufficient to decrease the contact resistivity of the silicon germanium layers to desired values.

Further attempts to decrease the contact resistance to the silicon germanium and similar films include the addition of another dopant, in which the first dopant (e.g., boron) may be soluble, and a high-temperature anneal process. Such techniques may be problematic because the use of the relatively high temperatures during the anneal process can lead to clustering of one or more of the dopants at a surface of the doped semiconductor films.

Furthermore, in some applications, it may be desirable to selectively deposit semiconductor material (e.g., highly-doped Group IV semiconductor material) with a first dopant (e.g., boron) and a second dopant (e.g., gallium, aluminum or indium). However, such techniques may heretofore not be well developed.

Accordingly, improved methods and systems for depositing doped semiconductor material are desired. Structures and devices formed using the methods and/or systems are also desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to methods of forming structures, to structures and devices formed using such methods, and to apparatus for performing the methods and/or for forming the structures and/or devices. While the ways in which various embodiments of the present disclosure address drawbacks of prior methods and systems are discussed in more detail below, in general, various embodiments of the disclosure provide improved methods of forming doped semiconductor layers that exhibit relatively low contact resistance. Additionally or alternatively, the doped semiconductor layers can be formed at relatively low temperatures, without the use of a step of annealing to improve the contact resistance of the doped semiconductor layers. Further, exemplary doped semiconductor layers can be selectively formed overlying a first portion of a substrate surface relative to a second portion of the substrate surface.

In accordance with exemplary embodiments of the disclosure, a method of forming a structure is disclosed. Exemplary methods include providing a substrate within a reaction chamber, forming a first doped semiconductor layer overlying the substrate, and forming a second doped semiconductor layer overlying the first doped semiconductor layer. The first doped semiconductor layer can include a first dopant and a second dopant. The second doped semiconductor layer can include the first dopant. The first doped semiconductor layer can include, for example, p-type or n-type doped Group IV semiconductor material. The second doped semiconductor layer can include, for example, p-type or n-type doped Group IV semiconductor material. Exemplary methods can include a step of etching first doped semiconductor layer material and second doped semiconductor layer material. The etching can be performed using a halide-containing gas, such as hydrogen chloride, chlorine or the like. Exemplary methods can include forming a cap layer overlying the second doped semiconductor layer. In such cases, a step of etching can include etching cap layer material. The cap layer can include, for example, semiconductor material, such as a Group IV semiconductor, and a dopant, such as the first dopant and/or the second dopant. As set forth in more detail below, various steps of exemplary methods described herein can be performed in the same reaction chamber or in different reaction chambers of, for example, the same cluster tool. The first doped semiconductor layer, the second doped semiconductor layer, and/or the cap layer can be selectively formed overlying a first portion of the surface of the substrate relative to a second portion of the substrate. The first portion of the surface of the substrate can comprise, for example, a monocrystalline semiconductor such as monocrystalline silicon, for example n-type monocrystalline czochralski silicon, for example n-type monocrystalline floatzone silicon, for example p-type monocrystalline czochraslki silicon, or p-type monocrystalline floatzone silicon. The second portion of the surface of the substrate can comprise, for example, a dielectric such as silicon oxide or a high-k dielectric or a low-k dielectric. Exemplary high-k dielectrics include hafnium oxide, zirconium oxide, and aluminum oxide. Exemplary low-k dielectrics include SiOC, SiOCN, SiN, SiNC, BN, etc.

In accordance with further exemplary embodiments of the disclosure, a structure is formed using a method as described herein. The structure can include a substrate having a first doped semiconductor layer overlying the substrate, and a second doped semiconductor layer overlying the first doped semiconductor layer. Exemplary structures can further include a cap layer.

In accordance with yet additional embodiments of the disclosure, a device or portion thereof can be formed using a method and/or a structure as described herein. The device can include a substrate, a first doped semiconductor layer, a second doped semiconductor layer, and a conducting layer overlying the second doped semiconductor layer. The first doped semiconductor layer and/or the second doped semiconductor layer can be used to form a source or drain region of the device, such as a field effect transistor (FET) (e.g., a FinFET).

In accordance with yet additional examples of the disclosure, a system to perform a method as described herein and/or to form a structure, device, or portion of either is disclosed.

Further described herein is a method of forming a structure, the method comprising the steps of: providing a substrate within a reaction chamber; forming a first doped semiconductor layer overlying the substrate; and forming a second doped semiconductor layer overlying the first doped semiconductor layer, wherein the first doped semiconductor layer comprises a first dopant and a second dopant, and wherein the second doped semiconductor layer comprises the first dopant.

In some embodiments, the first dopant comprises a first p-type dopant.

In some embodiments, the first p-type dopant is selected from one or more of B, Al, Ga, and In.

In some embodiments, the second dopant comprises a second p-type dopant.

In some embodiments, the second p-type dopant is selected from one or more of B, Al, Ga, and In.

In some embodiments, the first dopant comprises boron and the second dopant gallium.

In some embodiments, the method further comprises a step of forming a cap layer overlying the second doped semiconductor layer.

In some embodiments, the cap layer comprises semiconductor material.

In some embodiments, the cap layer comprises a cap dopant.

In some embodiments, the cap dopant comprises a p-type dopant.

In some embodiments, the p-type dopant comprises one or more of B, Al, Ga, and In.

In some embodiments, the first doped semiconductor layer is selectively formed on a first portion of a surface of the substrate.

In some embodiments, the second doped semiconductor layer is selectively formed overlying the first portion of the surface of the substrate.

Further described herein is a structure formed according to a method as described herein.

In some embodiments, the first doped semiconductor layer comprises about 1×10¹⁷ at/cm³ to about 5×10²¹ at/cm³, about 1×10¹⁷ at/cm³ to about 3×10²¹ at/cm³, about 1×10¹⁸ at/cm³ to about 2×10²¹ at/cm³, about 8×10¹⁸ at/cm³ to about 1×10²¹ at/cm³, greater than 1×10¹⁹ at/cm³, greater than 1×10²⁰ at/cm³, greater than 2.5×10²⁰ at/cm³, or greater than 5×10²⁰ at/cm³ one or more carriers.

In some embodiments, the first doped semiconductor layer comprises about 1×10¹⁷ at/cm³ to about 5×10²¹ at/cm³, about 1×10¹⁷ at/cm³ to about 3×10²¹ at/cm³, about 1×10¹⁸ at/cm³ to about 2×10²¹ at/cm³, about 8×10¹⁸ at/cm³ to about 1×10²¹ at/cm³, greater than 1×10¹⁹ at/cm³, greater than 1×10²⁰ at/cm³, greater than 2.5×10²⁰ at/cm³, or greater than 5×10²⁰ at/cm³ boron.

In some embodiments, the first doped semiconductor layer comprises about 10 at % to about 90 at %, about 30 at % to about 70 at %, or about 40 at % to about 50 at % silicon.

In some embodiments, the first doped semiconductor layer comprises about 10at % to about 90 at %, about 65 at % to about 30 at %, or about 60 at % to about 50 at % germanium.

In some embodiments, the first doped semiconductor layer comprises between about zero or greater than zero to about 5×10²¹ at/cm³, between about zero or greater than zero to about 3×10²¹ at/cm³, between about 8×10¹⁸ at/cm³ and about 9×10²⁰ at/cm³, or between about 1×10¹⁹ at/cm³ and about ×10¹⁹ at/cm³, or greater than 1×10²⁰ at/cm³ gallium.

In some embodiments, a thickness of the first doped semiconductor layer is between greater than zero or about 1 nm and about 50 nm, between about 2 nm and 20 nm, or between about 3 nm and 10 nm.

In some embodiments, a thickness of the second doped semiconductor layer is between about 1 nm and about 50 nm, between about 2 nm and 20 nm, or between about 3 nm and 10 nm.

In some embodiments, the second doped semiconductor layer comprises about 1×10¹⁷ at/cm³ to about 5×10²¹ at/cm³, about 1×10¹⁷ at/cm³ to about 3×10²¹ at/cm³, about 1×10¹⁸ at/cm³ to about 2×10²¹ at/cm³, about 8×10¹⁸ at/cm³ to about 1×10²¹ at/cm³, greater than 1×10¹⁹ at/cm³, greater than 1×10²⁰ at/cm³, greater than 2.5×10²⁰ at/cm³, or greater than 5×10²⁰ at/cm³ carriers.

In some embodiments, the second doped semiconductor layer comprises about 1×10¹⁷ at/cm³ to about 5×10²¹ at/cm³, about 1×10¹⁷ at/cm³ to about 3×10²¹ at/cm³, about 1×10¹⁸ at/cm³ to about 2×10²¹ at/cm³, about 8×10¹⁸ at/cm³ to about 1×10²¹ at/cm³, greater than 1×10¹⁹ at/cm³, greater than 1×10²⁰ at/cm³, greater than 2.5×10²⁰ at/cm³, or greater than 5×10²⁰ at/cm³ boron.

In some embodiments, the second doped semiconductor layer comprises about 10 at % to about 90 at %, about 30 at % to about 70 at %, or about 40 at % to about 50 at % silicon.

In some embodiments, the second doped semiconductor layer comprises about 10 at % to about 90 at %, about 65 at % to about 30 at %, or about 60 at % to about 50 at % germanium.

In some embodiments, a concentration of the second dopant in the first doped semiconductor layer is higher near a top surface relative to bulk first doped semiconductor layer material.

In some embodiments, a concentration of carbon in the first doped semiconductor layer is lower near a top surface relative to bulk first doped semiconductor layer material.

In some embodiments, a concentration of carbon within ±10 nm, ±5 nm or ±3 nm distance from a first doped semiconductor layer/second doped semiconductor layer interface is less than 1×10²¹ at/cm³, less than 1×10²⁰ at/cm³, less than 1×10¹⁹ at/cm³, less than 5×10¹⁸ at/cm³, less than 1×10¹⁸ at/cm³, less than 5×10¹⁷ at/cm³, less than 1×10¹⁷ at/cm³, or less than 5×10¹⁶ at/cm³.

In some embodiments, a concentration of gallium within ±10 nm, ±5 nm or ±3 nm distance from the first doped semiconductor layer/second doped semiconductor interface is less than 1×10²⁰ at/cm³, less than 1×10¹⁹ at/cm³, less than 5×10¹⁸ at/cm³, less than 1×10¹⁸ at/cm³, less than 5×10¹⁷ at/cm³, less than 1×10¹⁷ at/cm³, or less than 5×10¹⁶ at/cm³.

In some embodiments, a concentration of carbon within less than 10 nm, 5 nm or 3 nm or within 1 to 10 nm, 1 to 5 nm or 1 to 3 nm distance from a top of second doped semiconductor interface is less than 1×10²¹ at/cm³, less than 1×10²⁰ at/cm³, less than 5×10¹⁹ at/cm³, less than 1×10¹⁹ at/cm³, less than ×10¹⁸ at/cm³ or less than 1×10¹⁸ at/cm³.

In some embodiments, a concentration of gallium within less than 5 nm, less than 3 nm or less than 2 nm or within 1 to 5 nm, 1 to 3 nm distance from second doped semiconductor interface top interface is more than 1×10¹⁸ at/cm³, more than 5×10¹⁸ at/cm³, more than 1×10¹⁹ at/cm³, more than 5×10¹⁹ at/cm³, more than 1×10²⁰ at/cm³, more than 5×10²⁰ at/cm³, or more than 1×10²¹ at/cm³.

Further described herein is a device formed according to any of the method as described herein and/or using any of the structures as described herein.

In some embodiments, the device comprises a source region formed according to a method as described herein.

In some embodiments, the device comprises a drain region formed according to a method as described herein.

In some embodiments, the device further comprises a conducting layer overlying the second doped semiconductor layer.

Further described herein is a system configured to perform the method as described herein and/or to form a structure as described herein.

Further described herein is a system comprising: one or more reaction chambers; a gas injection system fluidly coupled to at least one of the one or more reaction chambers; a first gas source; a second gas source; a third gas source; an exhaust source; and a controller, wherein the controller is configured to control gas flow into the gas injection system to form a first doped semiconductor layer overlying a surface of a substrate, form a second doped semiconductor layer overlying the first doped semiconductor layer, and form a cap layer overlying the second doped semiconductor layer.

In some embodiments, the controller is configured to perform a step of etching the first doped semiconductor layer and second doped semiconductor layer overlying the second surface in the one or more reaction chambers.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIGS. 2 and 3 illustrate structures in accordance with exemplary embodiments of the disclosure.

FIG. 4 illustrates another method in accordance with exemplary embodiments of the disclosure.

FIGS. 5-10 illustrate structures in accordance with exemplary embodiments of the disclosure.

FIG. 11 illustrates a portion of a device in accordance with exemplary embodiments of the disclosure.

FIG. 12 illustrates a reactor system in accordance with additional exemplary embodiments of the disclosure.

FIG. 13 shows secondary ion mass spectroscopy (SIMS) measurement result illustrating advantageous properties of some embodiments of the methods according to the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming doped semiconductor layers on a surface of a substrate. Exemplary methods can be used to, for example, form source and/or drain regions of semiconductor devices that exhibit relatively high mobility, relatively low contact resistance, and that maintain the structure and composition of the deposited layers. For example, methods described herein can include forming a first doped semiconductor layer overlying a surface of a substrate and forming a second doped semiconductor layer overlying the first doped semiconductor. As set forth in more detail below, one or more of the steps of forming can be selective overlying a first area or material relative to a second area of material.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert (e.g., carrier) gases include He, Ar, H₂, N₂, and any combination thereof.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as a Group II-VI or Group III-V semiconductor, and can include one or more layers overlying or underlying the bulk material. Further, the substrate can include various features, such as recesses, protrusions, and the like formed within or on at least a portion of a layer of the substrate. As set forth in more detail below, a surface of a substrate can include two or more areas, wherein each of the two or more areas comprise different material and/or material with different crystalline structure.

As used herein, the term “epitaxial layer” can refer to a substantially single crystalline layer upon an underlying substantially single crystalline substrate or layer.

As used herein, the term “chemical vapor deposition” can refer to any process wherein a substrate is exposed to one or more volatile precursors, which react and/or decompose on a substrate surface to produce a desired deposition.

As used herein, the term “silicon germanium” can refer to a semiconductor material comprising silicon and/or germanium and can be represented as Si₁₋ₓGeₓ wherein 1≥x≥0, or 0.2≥x≥0.8, or 0.4≥x≥0.6, or materials comprising silicon and germanium having compositions as set forth herein.

As used herein, the term “film” and/or “layer” can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, the term “monocrystalline” may refer to a material that includes a substantial single crystal, i.e., a crystalline material that displays long range ordering. It should, however, be appreciated that a “monocrystalline” material may not be a perfect single crystal but may comprise various defects, stacking faults, atomic substitutions, and the like, as long as the “monocrystalline” material exhibits long range ordering.

As used herein, the term “non-monocrystalline” may refer to a material that does not comprise a substantial single crystal, i.e., a material which displays either short range ordering or no ordering of the crystalline structure. Non-monocrystalline materials may comprise polycrystalline materials which may display short range ordering and amorphous materials which may display substantially no ordering of the crystalline structure.

As used herein, a “structure” can include a substrate as described herein. Structures can include one or more layers overlying the substrate, such as one or more layers formed according to a method as described herein.

As used herein, the term “Group IV semiconductor” may refer to a semiconductor material comprising at least one of carbon (C), silicon (Si), germanium (Ge), tin (Sn), or alloys thereof.

As used herein, the term “Group IIIA dopant precursor” or “p-type dopant precursor” may refer to dopant precursor comprising at least one of boron (B), aluminum (AI), gallium (Ga), or indium (In). Similarly, a p-type dopant can include one or more of B, Al, Ga, and In.

As used herein, the term “Group V dopant precursor” or “n-type dopant precursor” may refer to dopant precursor comprising at least one of phosphorus (P), arsenic (As), and antimony (Sb). Similarly, an n-type dopant can include one or more of P, As, and Sb.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

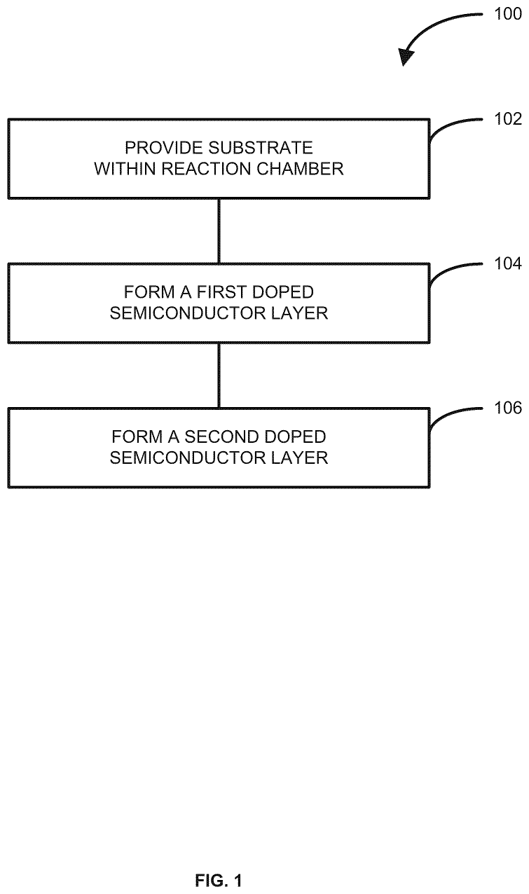

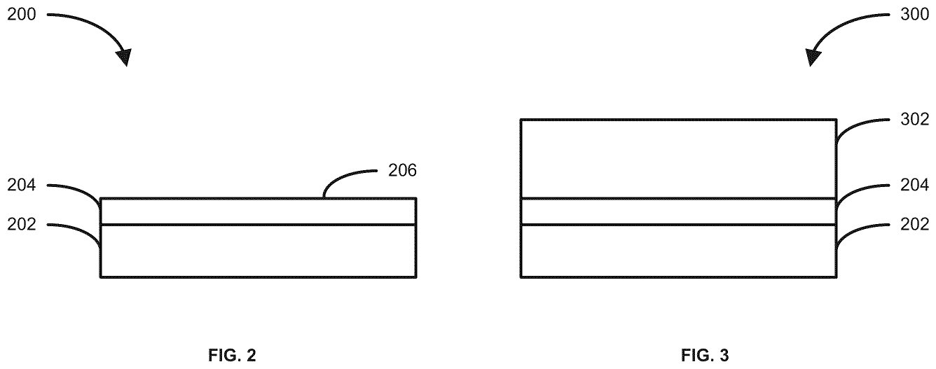

Turning now to the figures, FIG. 1 illustrates a method 100 in accordance with exemplary embodiments of the disclosure. FIGS. 2 and 3 illustrate structures 200 and 300 that can correspond to steps of method 100.

Method 100 includes the steps of providing a substrate within a reaction chamber (step 102), forming a first doped semiconductor layer (step 104), and forming a second doped semiconductor layer (step 106). Steps 104 and 106 can be repeated as desired.

During step 102, a substrate (e.g., substrate 202) as described herein is provided within a reaction chamber. As a non-limiting example, the reaction chamber used during step 102 may comprise a reaction chamber of a chemical vapor deposition system. However, it is also contemplated that other reaction chambers and alternative chemical vapor deposition systems may also be utilized to perform the embodiments of the present disclosure. The reaction chamber can be a stand-alone reaction chamber or part of a cluster tool.

Step 102 can include heating the substrate to a desired deposition temperature within the reaction chamber. In some embodiments of the disclosure, step 102 includes heating the substrate to a temperature of less than approximately 1100° C., or to a temperature of less than approximately 700° C., or to a temperature of less than approximately 650° C., or to a temperature of less than approximately 600° C., or to a temperature of less than approximately 550° C., or to a temperature of less than approximately 500° C., or to a temperature of less than approximately 450° C., or even to a temperature of less than approximately 400° C., or even to a temperature of less than approximately 300° C., or even to a temperature of less than approximately 250° C. For example, in some embodiments of the disclosure, heating the substrate to a deposition temperature may comprise heating the substrate to a temperature between approximately 400° C. and approximately 1100° C. or approximately 400° C. and approximately 700° C. For example, in some embodiments of the disclosure, heating the substrate to a deposition temperature may comprise heating the substrate to a temperature between approximately 290° C. and 400° C.

In addition to controlling the temperature of the substrate, a pressure within the reaction chamber may also be regulated. For example, in some embodiments of the disclosure, the pressure within the reaction chamber during step 102 may be less than 760 Torr, or less than 350 Torr, or less than 100 Torr, or less than 50 Torr, or less than 25 Torr, or even less than 10 Torr. In some embodiments, the pressure in the reaction chamber may be between 10 Torr and 760 Torr, between 10 Torr and 200 Torr, or between 10 Torr and 100 Torr.

During step 104, a first doped semiconductor layer 204 is formed overlying substrate 202. First doped semiconductor layer 204 may form as a (e.g., mono) crystalline material overlying at least a portion of substrate 202. Accordingly, at least a portion of surface 206 of first doped semiconductor layer 204 may be monocrystalline and serve as a template for further epitaxial layers.

First doped semiconductor layer 204 can include a Group IV semiconductor material. Exemplary Group IV semiconductors include silicon (e.g., n-type doped Si), silicon germanium (SiGe) (e.g., p-type doped SiGe), germanium (e.g., p-type doped Ge), and germanium tin (e.g., p-type doped GeSn).

In accordance with various embodiments of the disclosure, first doped semiconductor layer 204 includes a first dopant and a second dopant. In accordance with aspects of these embodiments, the first dopant and the second dopant are of the same type (n-type or p-type). Exemplary dopants include, for example, Group IIIA dopants as p-type dopants and Group V dopants as n-type dopants.

During step 104, one or more Group IV precursors and one or more Group IIIA and/or Group V dopant precursors are flowed into the reaction chamber—e.g., through one or more gas injectors, such as multi-port injectors (MPIs) including a plurality of individual port injectors for providing a gas mixture into the reaction chamber. Various combinations of the precursors can be supplied to one or more of the individual port injectors to fine tune concentration profiles as desired. To mitigate reaction with some dopants, such as gallium in the films as the films deposit, the precursors (e.g., all the precursors) may desirably be halide (e.g., chlorine) free. In other words, a chemical formula of a precursor, or component thereof, may not include Cl or other halide.

In some embodiments, a single Group IV precursor may be utilized during the deposition process; for example, a single Group IV precursor may be utilized when the Group IV semiconductor to be deposited comprises silicon (Si) or germanium (Ge). In some embodiments, two or more Group IV precursors may be utilized during the deposition process; for example, two or more Group IV precursors may be utilized when the Group IV semiconductor to be deposited comprises a Group IV semiconductor alloy including, but not limited to, silicon germanium, silicon germanium carbide (Si_{1-x-y}GeₓC_{y}), germanium tin (Ge₁₋ₓSnₓ), germanium silicon tin (Ge_{1-x-y}SiₓSn_{y}), germanium silicon tin carbide (Ge_{1-x-y}SiₓSn_{y}Cₓ), silicon tin (Si₁₋ₓSnₓ), silicon tin carbide (Si_{1-x-y}SnₓC_{y}), or silicon carbide (Si₁₋ₓCₓ).

Exemplary silicon precursors (e.g., for deposition of silicon-containing first doped semiconductor layer) may comprise one or more hydrogenated silicon precursors selected from the group comprising: silane (SiH₄), disilane (Si₂H₆), trisilane (Si₃H₈), tetrasilane (Si₄H₁₀), pentasilane (Si₅H₁₂), methylsilane (CH₃₋SiH₃), or other suitable silicon-containing precursor. Advantageously, the silicon precursor does not contain chlorine. Advantageously, the silicon precursor does not contain a halide.

Exemplary germanium precursors (e.g., for deposition of germanium-containing first doped semiconductor layer) may comprise at least one of germane (GeH₄), digermane (Ge₂H₆), trigermane (Ge₃H₈), or germylsilane (GeH₆Si), or other suitable germanium-containing precursor.

Exemplary tin precursors (e.g., for deposition of tin-containing first doped semiconductor layer) may comprise one tin tetrachloride (SnCl₄), SiH₄, tin deuteride (SnD₄), and other suitable tin-containing precursors.

A p-type (e.g., first) dopant precursor can include, for example, at least one of diborane (B₂H₆) or deuterium-diborane (B₂D₆), or one or more borohydrides. Exemplary borohydrides include gallium borohydride (Ga(BH₄)₃), aluminum borohydride (Al(BH₄)₃), and indium borohydride (In(BH₄)₃). In alternative embodiments of the disclosure, the p-type dopant precursor may comprise a borohydride having the formula YₓM(BH₄)₃₋ₓ, wherein Y is independently chosen from hydrogen, deuterium, chlorine, bromine, and iodine; M is a Group IIIA metal independently chosen from gallium, aluminum, and indium; and x is an integer from 0-2.

In some embodiments of the disclosure, the p-type dopant precursor includes one or more organic borohydrides having the general formula RₓM(BH₄)₃₋ₓ, wherein R is independently chosen from CH₃, C₂H₅, C₆H₅, CF₃SO₃, and NH₂; M is a Group IIIA metal independently chosen from gallium, aluminum and indium; and x is an integer from 1-3.

In some embodiments of the disclosure, the p-type dopant precursor can include one or more halides having the general formula ZₓMY₃₋ₓ, wherein Z is independently chosen from hydrogen, deuterium, chlorine, bromine, and iodine; M is a Group IIIA metal independently chosen from gallium, aluminum, and indium; Y is a halide independently chosen from chlorine, bromine, and iodine; and x is an integer from 0-3. In some embodiments of the disclosure, the halide dopant may comprise a dimer structure and therefore methods may comprise selecting the halide to comprise a halide having the formula (ZₓMY₃₋ₓ)₂, wherein Z is independently chosen from hydrogen, deuterium, chlorine, bromine, and iodine; M is a Group IIIA metal independently chosen from gallium, aluminum, and indium; Y is a halide independently chosen from chlorine, bromine, and iodine; and x is an integer from 0-3.

In some embodiments of the disclosure, the p-type dopant precursor can include one or more organohalides and may further comprise selecting the one or more organohalides to comprise an organohalide having the general formula RₓMY₃₋ₓ, wherein R is independently chosen from CH₃, C₂H₅, C₆H₅, CF₃SO₃, and NH₂; M is a group IIIA metal independently chosen from gallium, aluminum, and indium; Y is a halide independently chosen from chlorine, bromine, and iodine; and x is an integer from 0-3.

The selection of Group IIIA dopant precursors comprising an organic component may be further beneficial in the deposition of Group IV semiconductors. For example, carbon incorporation into a Group IV semiconductor may further increase the strain in the Group IV semiconductor being deposited. Therefore, in some embodiments of the disclosure, exposing the substrate to at least one Group IIIA precursor further comprises exposing the substrate to at least one of an organic borohydride or an organohalide. In further embodiments, exposing the substrate to at least one of an organic borohydride or an organohalide further comprises incorporating carbon into the first doped semiconductor layer, the atomic percentage (at-%) of carbon in the first doped semiconductor layer being greater than, for example, approximately 0.5 at %.

In some embodiments of the disclosure, it may be beneficial to deposit the first and/or second doped semiconductor layer without incorporating substantially any carbon into the deposited semiconductor layer. However, since metalorganic dopant precursors can comprise an organic component, i.e., a carbon containing component, it may be difficult to minimize the carbon incorporation into the first doped semiconductor layer when using a metalorganic dopant precursor. However, the methods of the disclosure may deposit select first doped semiconductor layers utilizing metalorganic or other precursor dopants without any significant carbon incorporation into the semiconductor layer. As a non-limiting example embodiment, a (e.g., selective) deposition method may comprise depositing a layer comprising germanium (Ge) that is substantially free of carbon.

In some embodiments of the disclosure, two or more dopant species may be incorporated into first doped semiconductor layer 204 using a single dopant precursor. For example, in some embodiments, step 104 includes exposing the substrate to one or more Group IIIA dopant precursors, such as a borohydride or an organic borohydride and/or other Group IIIA precursor. In embodiments utilizing borohydrides or organic borohydrides, the dopant precursor can included boron (B) in addition to a further (e.g., second) Group IIIA dopant (e.g., gallium, aluminum, or indium). Therefore, utilizing borohydrides or organic borohydrides comprises incorporating a first dopant and a further (second) dopant into the first doped semiconductor layer. Such methods may be utilized to further increase the dopant concentration in the Group IV semiconductor without a corresponding decrease in crystalline quality of the Group IV semiconductor.

Precursors for the second dopant can, for example, include at least one Group IIIA metalorganic dopant precursor and/or a Group V precursor. In some cases, it may be desirable to use halogen-free Group IIIA precursors for the first and/or second dopant source.

In some embodiments, the second dopant precursor can comprise at least one metalorganic compound of a gallium dopant, an aluminum dopant and/or an indium dopant. The gallium dopant precursor can comprise, for example, a gallium alkyl. The gallium dopant precursor can comprise, for example, at least one of trimethylgallium (TMG) or triethylgallium (TEG), tritertiarybutylgallium (TTBGa), Tri-isopropyl gallium (TiPGa), galliumtrichlorine (GaCl₃), Ga(BH₄)₃, diethylgallium chloride (DeGaCl), RGaCl₂, GaR₃, GaHₓ, wherein R can be, for example, an alkyl group, linear or branched, such as, an ethyl, butyl, or propyl, group. The aluminum dopant precursor can comprise at least one of trimethylaluminum (TMA) or triethylaluminum (TEA). The indium dopant precursor can comprise at least one of: trimethylindium (TMI), triethylindium (TEI), cyclopentadienylindium (InCp), di-isopropylmethylindium (DIPMeIn), or ethyldimethylindium (EDMIn).

In some embodiments, the gallium dopant precursor can comprise, for example, at least one of trimethylgallium (TMG) or triethylgallium (TEG), tritertiarybutylgallium (TTBGa), Tri-isopropyl gallium (TiPGa), Ga(BH₄)₃, GaR₃, GaHₓ, wherein R can be, for example, an alkyl group, linear or branched, such as, an ethyl, butyl, or propyl, group.

In some embodiments, a p-type dopant precursor may be provided in diluted form and the diluted form may comprise approximately 0.1% to approximately 100% dopant precursor in a carrier gas (if present).

An n-type dopant precursor can include, for example, at least one of phosphine and arsine. In some embodiments, the n-type dopant precursor may be provided in diluted form and the diluted form may comprise approximately 1% to approximately 5% dopant precursor in a carrier gas.

A thickness of the first doped semiconductor layer 204 formed during step 104 can be between greater than zero or about 1 nm and about 50 nm, between about 2 nm and about 20 nm, or between about 3 nm and about 10 nm. A concentration of one or more p-type dopants (e.g., boron) in first doped semiconductor layer 204 (e.g., doped Si₁₋ₓGeₓ) can be about 1×10¹⁷ at/cm³ to about 5×10²¹ at/cm³, about 1×10¹⁷ at/cm³ to about 3×10²¹ at/cm³, about 1×10¹⁸ at/cm³ to about 2×10²¹ at/cm³, about 8×10¹⁸ at/cm³ to about 1×10²¹ at/cm³, greater than 1×10¹⁹ at/cm³, greater than 1×10²⁰ at/cm³, greater than 2.5×10²⁰ at/cm³, or greater than 5×10²⁰ at/cm³. A concentration of a second p-type dopant (e.g., aluminum, gallium, or indium) can be between about zero or greater than zero to about 3×10²¹ at/cm³, between about 8×10¹⁸ at/cm³ and about 9×10²⁰ at/cm³, or between about 1×10¹⁹ at/cm³ and about 9×10¹⁹ at/cm³, or greater than 1×10²⁰ at/cm³.

For silicon germanium layers, first doped semiconductor layer 204 can include about 10% to about 90%, or about 30% to about 70%, or about 40% to about 50% silicon and/or about 10% to about 90%, or about 65% to about 30%, or about 60% to about 50% germanium. In some embodiments, the germanium (and/or other component) content within first doped semiconductor layer 204 may not be constant, but rather may be varied, such that the germanium content (and/or other component) may have a graded composition within first doped semiconductor layer 204.

During step 106, a second doped semiconductor layer 302 is (e.g., epitaxially) formed overlying the first doped semiconductor layer 204 over at least a portion of substrate 202, as illustrated in FIG. 3. Second doped semiconductor layer 302 can include (e.g., Group IV) semiconductor material and a first dopant (e.g., the same first dopant or same type first dopant in the first doped semiconductor layer).

By forming (e.g., growing) first doped semiconductor layer 204 comprising a first dopant and a second dopant prior to forming (e.g., growing) second doped semiconductor layer 302 comprising the first dopant, structures with desired properties can be formed. For example, the second dopant can be diffused to a top and/or carbon can be trapped in the layer 204, thereby providing desired properties, such as low contact resistance. Moreover, the heavier atomic mass of a second dopant (e.g., Ga) as compared to a first dopant (e.g., B) may be preferred for the formation of shallow junctions by minimizing the channeling effect. By way of example, by forming a SiGe:B:Ga prior to a SiGe:B layer, Ga can be diffused to the SiGe:B layer surface, while the C can be trapped inside the original SiGe:B:Ga layer. With this, an amount of carbon at the surface of the SiGe:B layer can be reduced. In some embodiments the carbon concentration within ±10 nm, ±5 nm or ±3 nm distance from the first doped semiconductor layer/second doped semiconductor layer (e.g., SiGe:B:Ga/SiGe:B)—interface is less than 5×10²¹ at/cm³, less than 1×10²¹ at/cm³, less than 1×10²⁰ at/cm³, less than 1×10¹⁹ at/cm³, less than 5×10¹⁸ at/cm³, less than 1×10¹⁸ at/cm³, less than5×10¹⁷ at/cm³, less than 1×10¹⁷ at/cm³, or less than 5×10¹⁶ at/cm³. In some embodiments the Ga concentration within ±10 nm, ±5 nm or ±3 nm distance from the first doped semiconductor layer/second doped semiconductor (e.g., SiGe:B:Ga/SiGe:B) interface is less than 1×10²⁰ at/cm³, less than 1×10¹⁹ at/cm³, less than 5×10¹⁸ at/cm³, less than 1×10¹⁸ at/cm³, less than 5×10¹⁷ at/cm³, less than 1×10¹⁷ at/cm³, or less than 5×10¹⁶ at/cm³. In some embodiments the carbon concentration within less than 10 nm, 5 nm or 3 nm or within 1 to 10 nm, 1 to 5 nm or 1 to 3 nm distance from second doped semiconductor layer (e.g., SiGe:B)—top interface is less than 5×10²¹ at/cm³, less than 1×10²¹ at/cm³, less than ×10²⁰ at/cm³, less than 5×10¹⁹ at/cm³, less than 1×10¹⁹ at/cm³, less than 5×10¹⁸ at/cm³ or less than 1×10¹⁸ at/cm³. In some embodiments the Ga concentration within less than 5 nm, less than 3 nm or less than 2 nm or within 1 to 5 nm, 1 to 3 nm distance from second doped semiconductor layer (e.g., SiGe:B)—top interface is more than 1×10¹⁸ at/cm³, more than 5×10¹⁸ at/cm³, more than 1×10¹⁹ at/cm³, more than 5×10¹⁹ at/cm³, more than 1×10²⁰ at/cm³, more than 5×10²⁰ at/cm³, or more than 1×10²¹ at/cm³.

A concentration of the first dopant in the second doped semiconductor layer 302 can range from about 1×10¹⁷ at/cm³ to about 5×10²¹ at/cm³, or about 1×10¹⁷ at/cm³ to about 3×10²¹ at/cm³, or about 1×10¹⁸ at/cm³ to about 2×10²¹ at/cm³, or about 8×10¹⁸ at/cm³ to about 1×10²¹ at/cm³ or greater than 1×10¹⁹ at/cm³ dopant or greater than 1×10²⁰ carriers per cubic centimeter, or greater than 2.5×10²⁰ carriers per cubic centimeter, or even greater than 5×10²⁰ carriers per cubic centimeter. Further, by way of particular example, the second doped semiconductor layer can include about 10% to about 90%, or about 30% to about 70%, or about 40% to about 50% silicon and/or about 10% to about 90%, or about 65% to about 30%, or about 60% to about 50% germanium. A thickness of the second doped semiconductor layer 302 can be between about 1 nm and about 50 nm, between about 2 nm and 20 nm, or between about 3 nm and 10 nm.

Precursors for the (e.g., Group IV) semiconductor material and for the first dopant for step 106 can be the same or similar to those described above in connection with step 104.

Step 106 can be performed in the same reaction chamber used during step 104. Alternatively, step 106 can be performed in another reaction chamber, such as another reaction chamber in the same cluster tool as the reaction chamber used during step 104 or of another reactor system. A temperature and/or pressure for step 106 can be the same or similar to the temperature and/or pressure described above in connection with step 104.

Secondary-ion mass spectrometry (SIMS) data for a SiGe:B:Ga/SiGe:B stack formed according to method 100 confirm that carbon atoms originally in an SiGe:B:Ga layer appear to stay in the SiGe:B:Ga layer (layer 204) and gallium in layer 204 appears to segregate towards a top surface of layer 302, thereby providing a structure with relatively low contact resistance.

As discussed in more detail below, exemplary methods can also include a step of forming a cap layer. In accordance with some embodiments of the disclosure, one or more of the first doped semiconductor layer, the second doped semiconductor layer, and a cap layer can be selectively formed over one portion (e.g., comprising a first material and/or having a first (e.g., crystalline) structure) of a substrate relative to another portion (e.g., comprising a second material and/or having a second (e.g., non-crystalline) structure).

A selective deposition process as described herein can involve a greater amount of material remaining on a first surface relative to a second surface. For example, the selective process may result in a greater amount of the first doped semiconductor layer remaining in the first area compared to any first doped semiconductor layer remaining in the second area and/or a greater amount of the second doped semiconductor layer remaining in the first area compared to any second doped semiconductor layer remaining in the second area. In some embodiments of the disclosure, the selectivity of the deposition process can be expressed as the ratio of material formed on the first surface (or in the first area) relative to the amount of material formed on the first and second surfaces (or areas) combined. For example, if 10 nm of the first doped semiconductor layer remains in the first area and 1 nm of the first doped semiconductor layer remains in the second area, the selective deposition process will be considered to have 91% selectivity. In some embodiments, the selectivity of the methods disclosed herein may be above about 80%, above about 90%, above about 95%, 99.5%, 98%, 99%, or even about 100%.

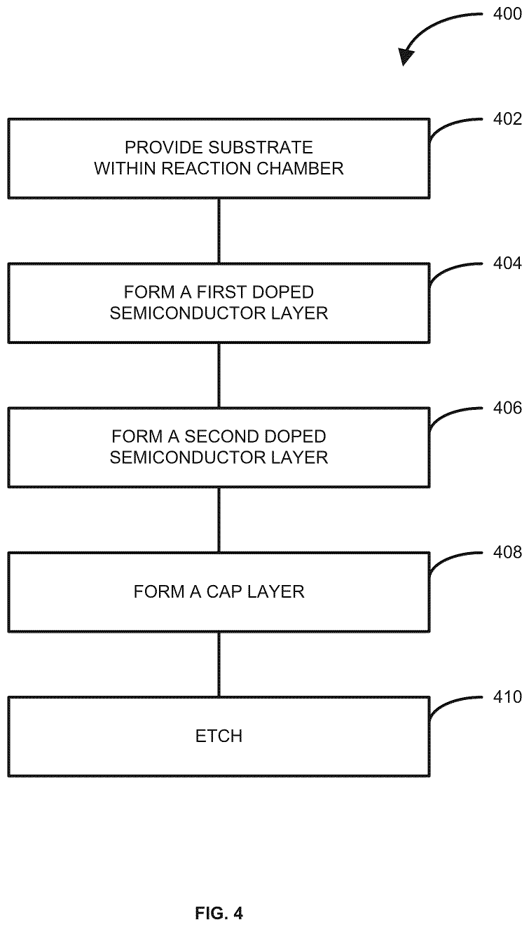

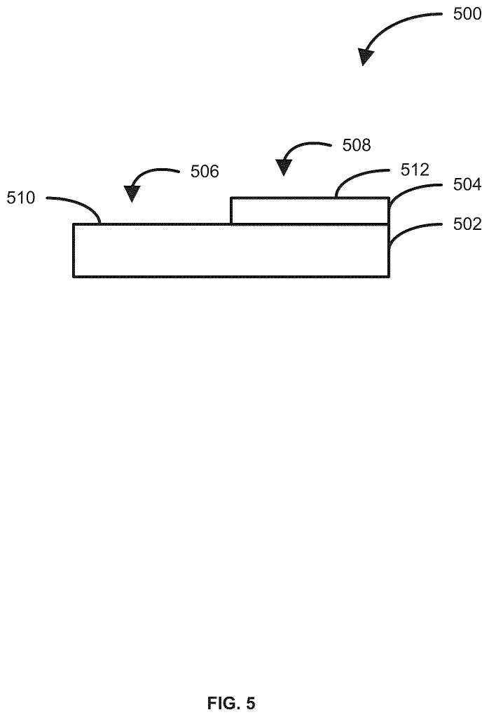

FIG. 4 illustrates a method 400 for selective formation of one or more of a first doped semiconductor layer, a second doped semiconductor layer, and a cap layer in accordance with exemplary embodiments of the disclosure. FIGS. 5-10 illustrate substrate 500 and structures 600, 700, 800, 900, and 1000 that can correspond to steps of method 400.

Method 400 includes the steps of providing a substrate within a reaction chamber (step 402), forming a first doped semiconductor layer (step 404), forming a second doped semiconductor layer (step 406), forming a cap layer (step 408), and etching (step 410).

Method 400 can be the same or similar to method 100, except method 100 includes the steps of forming a cap layer (step 408) and etching (step 410). Steps 402-406 can be the same or similar to steps 102-106 described above. For example, the steps can be performed in the same type of reaction chamber, can be performed at the same or similar temperatures, can be performed at the same or similar pressures, and/or can be performed using one or more (e.g., all) of the same precursors.

With reference to FIG. 4 and FIG. 5, a substrate (or structure) 500 provided during step 402 can include a first area 506 comprising a first material (e.g., (mono) crystalline bulk material 202) and a second area 508 comprising a second material (e.g., non-monocrystalline material 504). First area 506 can include a monocrystalline surface 510; second area 508 can include a non-monocrystalline surface 512, such as a polycrystalline surface or an amorphous surface. Monocrystalline surface 510 may include semiconductor material, for example, one or more Group IV semiconductor materials, such as silicon (Si), silicon germanium (SiGe), germanium tin (GeSn), silicon germanium tin (SiGeSn), or germanium (Ge). Non-monocrystalline surface 512 may include, for example, dielectric materials, such as an oxide, an oxynitride, a nitride, an oxycarbide, or an oxycarbide nitride, including, for example, a silicon oxide, silicon nitride, silicon oxynitride, silicon carbide or any mixtures thereof, such as SiOC, SiOCN, SiON.

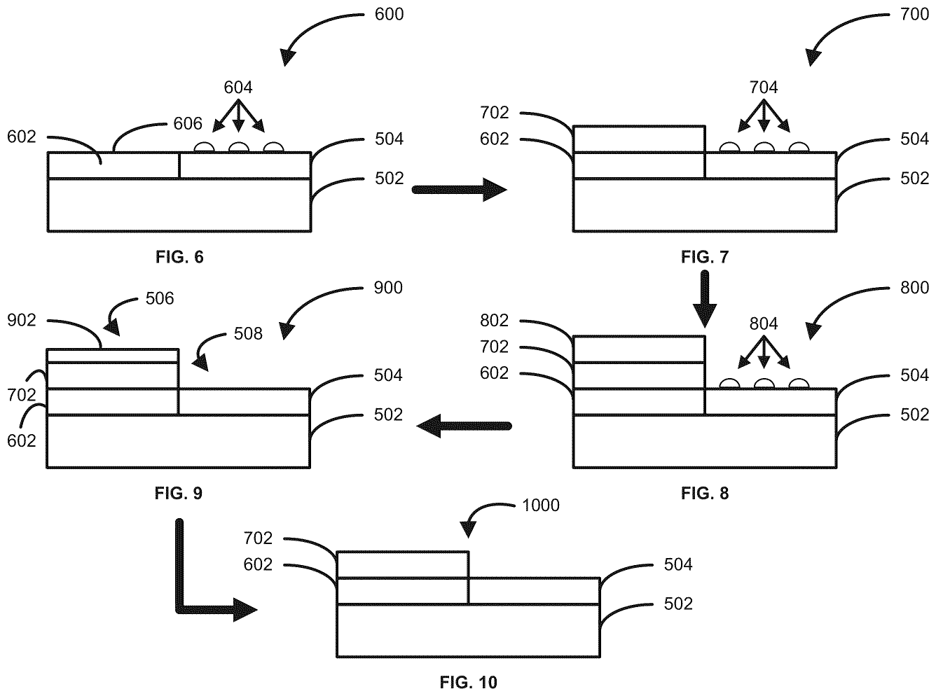

During step 404, a first doped semiconductor layer 602 can be selectively deposited overlying the first material (e.g., bulk material 502) in first area 206 relative to the second material (e.g., non-monocrystalline material 504) in second area 508, as illustrated in FIG. 6. First doped semiconductor layer 602 may form as a (e.g., mono) crystalline material overlying the first area/surface (e.g., area 506/surface 210). A surface 606 of first doped semiconductor layer 602 may therefore be monocrystalline and serve as a template for further epitaxial layers.

As further illustrated in FIG. 6, structure 600, including the first doped semiconductor layer 602 selectively formed in first area 506, can include some—e.g., nuclei and/or clusters—components 604 of first doped semiconductor material that form in second area 508. In such cases, an etch process, described in more detail below, can be used to remove components 604. In other cases, a nucleation delay of the first doped semiconductor layer may be high enough on the second/non-monocrystalline surface 512 relative to the first surface 510, such that components 604 do not form. In such cases, an etch step may not be desired. By way of particular example, a nucleation delay can be about 2 nm or more, 5 nm or more, 10 nm or more

First doped semiconductor layer 602 can include any of the materials described above in connection with first doped semiconductor layer 204. For example, first doped semiconductor layer 602 can include Group IV semiconductor material incorporating a first dopant and a second dopant as described above. A thickness and/or composition of first doped semiconductor layer 602 can be the same or similar to the thickness and/or composition of first doped semiconductor layer 204.

During step 406, a second doped semiconductor layer 702 is selectively (e.g., epitaxially) formed overlying the first doped semiconductor layer 602, as illustrated in FIG. 7. Second doped semiconductor layer 702 can include any of the materials described above in connection with second doped semiconductor layer 302. For example, second doped semiconductor layer 702 can include Group IV semiconductor material incorporating a first dopant as described above. A thickness and/or composition of second doped semiconductor layer 702 can be the same or similar to the thickness and/or composition of second doped semiconductor layer 302.

Structure 700 can also include—e.g., nuclei and/or clusters—components 704 of first and/or second doped semiconductor material that form in second area 508. In such cases, an etch process, described in more detail below, can be used to remove components 704. In other cases, a nucleation delay of the second doped semiconductor layer may be high enough in area 508 relative to area 506, such that components 704 do not form. By way of particular example, a nucleation delay can be about 10 nm or more.

During step 408, a cap layer 802 is selectively (e.g., epitaxially) formed overlying second doped semiconductor layer 702, as illustrated in FIG. 8. Cap layer 802 can include, for example, a single-element Group IV semiconductor, which can be doped. The dopant in layer 802 can be of the same type of dopant or the same dopant as the first dopant in layer 602 and/or layer 702. Structure 800 can also include—e.g., nuclei and/or clusters—components 804 of first and/or second doped semiconductor material and/or cap material that form in second area 508. In such cases, an etch process, described in more detail below, can be used to remove components 804. In other cases, a nucleation delay of the cap layer may be high enough in area 508 relative to area 506, such that components 804 do not form.

Use of cap layer 802 may decrease, and possibly cease, any second dopant (e.g., Al, Ga, or In) segregation. By way of illustrating with a particular example, SiGe:B/SiGe:B:Ga epitaxial layers can remain intact and keep their original characteristics and properties by employing cap layer 802 as a sacrificial layer. Thus, it is possible to have a selective SiGe:B:Ga or similar film process that can be used for S/D applications.

A cap layer 802 may consist, for example, of monocrystalline silicon, and the cap layer may be doped, e.g. with a p-type dopant. Suitable p-type dopants include boron and gallium. In some embodiments, the cap-layer may be doped with both boron and gallium. Accordingly, the cap layer may be grown using a silicon precursor and optionally using a boron precursor and/or a gallium precursor. Suitable silicon precursors include silanes such as SiH₄ and Si₂H₆. Suitable boron precursors include boranes such as B₂H₆. Suitable gallium precursors include organometallic gallium precursors, e.g. gallium alkyls, e.g. triethylgallium.

During step 410, any material deposited in area 508 during one or more of steps 404-408 can be removed by etching. Cap layer 802 can be used to protect layer 702 during step 410. For example, both (e.g., monocrystalline semiconductor) material in first area 506 and (e.g., non-monocrystalline) material in second area 508 may be exposed to an etchant gas. The etchant may remove (e.g., non-monocrystalline) components 804 in second area 508 at a higher rather than (e.g., monocrystalline semiconductor—such as cap layer 808) material in first area 506 to form structure 900. Further, there may be less deposited material in second area 508 relative to area 506.

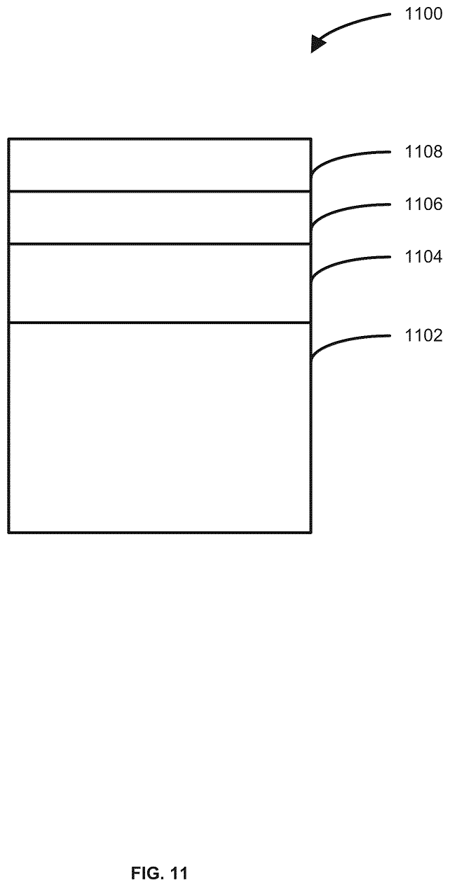

As illustrated in FIG. 9, a portion 902 of cap layer 802 can remain after all or substantially all of any material deposited in area 508 is removed. A remaining portion of the cap layer (802) can, for example, form a silicide when a metal contact is formed on the second doped semiconductor layer. Etch step 410 can optionally continue to remove all or substantially all of cap layer 802, as illustrated in FIG. 10. This can be useful, for example, when a metal contact is used that does not form a silicide. Step 410 can also be used to refresh the second material for the subsequent processing.

An etchant gas used during step 410 may comprise, for example, a halogen-containing gas or halide gas—e.g., at least one of chlorine (Cl₂) or hydrogen chloride (HCl).

Step 410 can be performed in the same reaction chamber used during step 404 and/or 406. Alternatively, step 410 can be performed in another reaction chamber, such as another reaction chamber in the same (or other) cluster tool as the reaction chamber used during step 404 and/or 406. A temperature and/or pressure for step 410 can be the same or similar to the temperature and/or pressure described above in connection with step 404 and/or 406. One or more of step 404-410 can be repeated as desired.

In some embodiments, the second doped semiconductor layer can be a germanium layer. Advantageously the second doped semiconductor layer may be a p-type doped germanium layer. Boron and/or gallium may be used as a dopant. Advantageously, the germanium layer is doped with boron and gallium. Accordingly, the second doped semiconductor layer may be grown in a process employing a germanium precursor, and optionally a boron precursor and/or a gallium precursor. Suitable germanium precursors include germanes such as germane (GeH₄), digermane (Ge₂H₆), and trigermane (Ge₃H₃). Alternatively, a precursor comprising germanium, silicon, and hydrogen such as germylsilane (GeH₆Si) may be used as a germanium precursor. Suitable boron precursors comprise borohydrides such as diborane or deuterium-diborane. The gallium precursor can comprise, for example, a gallium alkyl such as trimethylgallium (TMG), triethylgallium (TEG), Tri-isopropyl gallium (TiPGa), or tritertiarybutylgallium (TTBGa). Alternatively, the gallium precursor may comprise a gallium halide, e.g. a gallium chloride, such as galliumtrichloride (GaCl₃). Alternatively, the gallium precursor may comprise two alkyl ligands and a halide ligand, such as diethylgallium chloride (DeGaCl). Alternatively, the gallium precursor may comprise a gallium borohydride, such as Ga(BH₄)₃. In some embodiments, the gallium precursor is GaH₃. In some embodiments, the gallium precursor is selected from R₂GaCl, RGaCl₂, GaR₃, wherein R is ethyl, butyl, or propyl. In some embodiments, such a doped germanium layer used as a second doped semiconductor layer can comprise boron in a concentration of at least ×10¹⁷ at/cm³ to at most 5×10²¹ at/cm³, or of at least ×10¹⁸ at/cm³ to at most 2×10²¹ at/cm³, or of at least 8×10¹⁸ at/cm³ to at most 1×10²¹ at/cm³ or of at least 1×10¹⁹ at/cm³ dopant to at most 1×10²⁰ at/cm³, or greater than 2.5×10²⁰ at/cm³, or even greater than 5×10²⁰ at/cm³. In some embodiments, such a doped germanium layer can comprise gallium in a concentration of at most 3×10²¹ at/cm³, or of at least 8×10¹⁸ at/cm³ to at most 9×10²⁰ at/cm³, or of at least 1×10¹⁹ at/cm³ to at most 9×10¹⁹ at/cm³ or of at least 1×10²⁰ at/cm³. In some embodiments, such a doped germanium layer can be grown at a temperature of at least 250° C. to at most 800° C., or of at least 300° C. to at most 450° C. In some embodiments, such a doped germanium layer can be grown at a pressure of at least 10 Torr to at most 760 Torr.

FIG. 11 illustrates a portion of a device 1100 in accordance with additional examples of the disclosure. Portion of a device 1100 includes a substrate 1102, a first doped semiconductor layer 1104, a second doped semiconductor layer 1106, and a conducting layer 1108.

Substrate 1102 can be or include any of the substrate material described herein. For example, substrate 1102 can be the same as substrate 202 and/or substrate 502.

First doped semiconductor layer 1104 can be the same or similar to first doped semiconductor layer 204 or 602 described above. Similarly, second doped semiconductor layer 1106 can be the same or similar to second doped semiconductor layer 302 or 702 described above. First doped semiconductor layer 1104 and/or second doped semiconductor layer 1106 can be used to form a source or drain region of a field effect transistor (FET), such as a source or drain region of a FinFET or other FET device. Use of first doped semiconductor layer 1104 can reduce a contact resistance between conducting layer 1108 and the underlying doped semiconductor layer.

Conducting layer 1108 can include, for example, metal, such as titanium, nickel, cobalt, nickel platinum alloy, or the like. By way of particular examples, a contact resistance of a gallium doped p-type doped silicon germanium (e.g., SiGe:B:Ga) layer 1106 can be lower than 10⁻⁹ Ω.cm² to about 5×10⁻¹⁰ Ω.cm², about 5×10⁻¹⁰ Ω.cm² to about 2×10⁻¹⁰ Ω.cm², or about 2×10⁻¹⁰ Ω.cm² to about 1×10^{-10 Ω.}cm² without annealing.

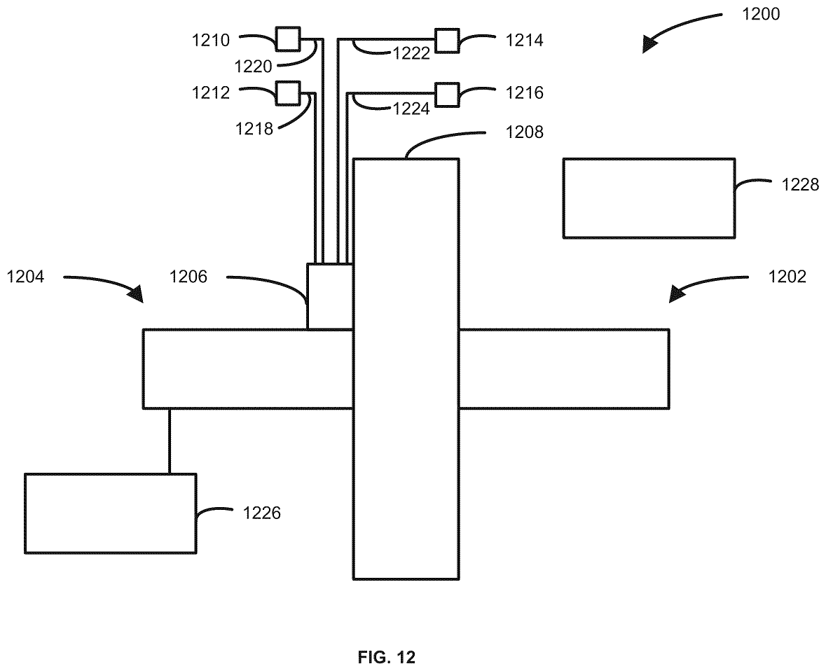

FIG. 12 illustrates a system 1200 in accordance with yet additional exemplary embodiments of the disclosure. System 1200 can be used to perform a method as described herein and/or form a structure or device portion as described herein.

In the illustrated example, system 1200 includes an optional substrate handling system 1202, one or more reaction chambers 1204, a gas injection system 1206, and optionally a wall 1208 disposed between reaction chamber(s) 1204 and substrate handling system 1202. System 1200 can also include a first gas source 1210, a second gas source 1212, a third gas source 1214, a fourth gas source 1216, an exhaust source 1226, and a controller 1228.

Although illustrated with four gas sources 1210-1216, system 1200 can include any suitable number of gas sources. Gas sources 1210-1216 can each include, for example, a precursor gas, such as a precursor (e.g., Group IV, p-type dopant precursors, and/or n-type dopant precursors) as described above, including mixtures of such precursors and/or mixtures of one or more precursors with a carrier gas, such as hydrogen, nitrogen, argon, helium or the like. Additionally or alternatively, one of gas sources 1210-1216 or another gas source can include an etchant, such as a halide—e.g., a chlorine-containing gas, such as hydrogen chloride and/or chlorine. Gas sources 1210-1216 can be coupled to reaction chamber 1204 via lines 1218-1224, which can each include flow controllers, valves, heaters, and the like.

System 1200 can include any suitable number of reaction chambers 1204 and substrate handling systems 1202. Further, one or more reaction chambers 1204 can be or include a cross-flow, cold wall epitaxial reaction chamber.

Exhaust source 1226 can include one or more vacuum pumps.

Controller 1228 can be configured to perform various functions and/or steps as described herein. For example, controller 1228 can be configured to control gas flow into the gas injection system to form a first doped semiconductor layer overlying the substrate and forming a second doped semiconductor layer overlying the first doped semiconductor layer, as described above. Controller 1228 can include one or more microprocessors, memory elements, and/or switching elements to perform the various functions. Although illustrated as a single unit, controller 1228 can alternatively comprise multiple devices. By way of examples, controller 1228 can be used to control gas flow (e.g., by monitoring flow rates of precursors and/or other gases from sources 1210-1216 and/or controlling valves, motors, heaters, and the like). Further, when system 1200 includes two or more reaction chambers, the two or more reaction chambers can be coupled to the same/shared controller.

During operation of reactor system 1200, substrates, such as semiconductor wafers (not illustrated), are transferred from, e.g., substrate handling system 1202 to reaction chamber 1204. Once substrate(s) are transferred to reaction chamber 1204, one or more gases from gas sources 1210-1216, such as precursors, dopants, carrier gases, etchants, and/or purge gases, are introduced into reaction chamber 1204 via gas injection system 1206. Gas injection system 1206 can be used to meter and control gas flow of one or more gases (e.g., from one or more gas sources 1210-1216) during substrate processing and to provide desired flows of such gas or gasses to multiple sites within reaction chamber 1204.

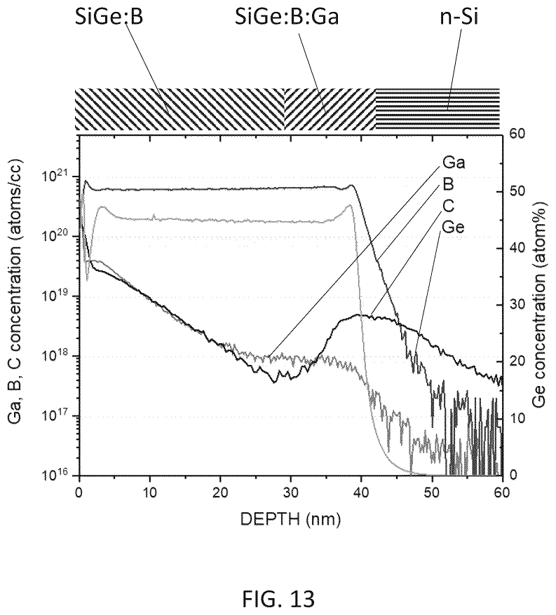

FIG. 13 shows secondary ion mass spectroscopy (SIMS) measurement results illustrating advantageous properties of some embodiments of the methods according to the present disclosure. In particular, the SIMS measurements were performed on a sample comprising a first doped semiconductor layer grown on an n-type monocrystalline silicon substrate, though another substrate such as a p-type monocrystalline silicon substrate might be used as well. A second doped semiconductor layer was grown on the first doped semiconductor layer. The first doped semiconductor layer was grown using a gallium precursor, a boron precursor, a silicon precursor, and a germanium precursor. Thus, in these embodiments B is used as a first dopant and Ga is used as a second dopant during growth of the first semiconductor layer. The second doped semiconductor layer was grown using a boron precursor, a silicon precursor, and a germanium precursor. Thus, in this exemplary embodiment, both the first and the second doped semiconductor layers are p-type silicon germanium. The results of FIG. 13 were based on a process using the following precursors and process conditions, during growth of both the first doped semiconductor layer and during growth of the second doped semiconductor layer: the susceptor was maintained at a temperature of at least 450° C. to at most 550° C., in particular 500° C., as measured by a pyrometer suspended above the wafer in the reaction chamber, at a pressure of at least 30 Torr to at most 50 Torr, in particular 40 Torr. A silane, in particular SiH₄, was used as a silicon precursor. A germane, in particular GeH₄, was used as a germanium precursor. A borohydride, in particular B₂H₆, was used as a boron precursor. During growth of the first doped semiconductor layer, a gallium precursor was additionally provided to the reaction chamber. In the process according to the present embodiment, a gallium alkyl, in particular triethylgallium, was used as a gallium precursor. In the embodiment SIMS measurements of which are shown in FIG. 13, the following flow rates were used, though other flow rates may be used as desired in order arrive at other layer compositions: an SiH₄ flow rate, of at least 30 sccm to at most 120 sccm, in particular 60 sccm was used; a GeH₄ flow rate of at least 170 sscm to at most 650 sccm, in particular 330 sccm was used, a B₂H₆ flow rate of at least 2 sccm to at most 10 sccm, in particular 5 sccm was used; a triethylgallium flow rate of at least 3 sccm to at most 12 sccm, in particular 3 sccm was used. The SIMS measurements of FIG. 13 show an increasing gallium concentration towards the surface of the doped semiconductor layer (i.e. towards depth 0 nm). Without the invention being bound to any particular theory or mode of operation, this is believed to be caused by gallium surface segregation. This effect is advantageously used in the present methods to achieve a high surface gallium concentration which, in turn, can lead to low contact resistance of metal contacts formed on the second doped semiconductor layer. The SIMS measurements show a carbon concentration which exhibits a peak where the first doped semiconductor layer (SiGe:B:Ga in this case) is located. This carbon peak is caused by carbon that ends up in the first doped semiconductor layer from the metalorganic gallium precursor which is used. During growth of the second doped semiconductor layer, no gallium precursor or other carbon-containing precursors are, in these embodiments, used, such that the second doped semiconductor layer is substantially free of carbon. Thus, by employing this specific sequence of a first doped semiconductor layer and a second doped semiconductor layer, a high gallium surface concentration and a low carbon surface concentration can be obtained, which can result in excellent contact resistance. Note that FIG. 13 shows an apparent increase in carbon concentration towards the surface of the second doped semiconductor layer (C apparently increasing from depth 30 nm to depth 0 nm). Note that this is an artifact, a knock-on effect, caused by carbon adsorption on the sample surface, and the carbon concentration does not actually increase towards the sample surface.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A system comprising:
one or more reaction chambers;
a gas injection system fluidly coupled to at least one of the one or more reaction chambers;
a first gas source;
a second gas source;
a third gas source;
an exhaust source; and
a controller,
wherein the controller is configured to control gas flow into the gas injection system to form a first doped semiconductor layer overlying a surface of a substrate and form a second doped semiconductor layer overlying the first doped semiconductor layer, and
wherein the first doped semiconductor layer comprises a first dopant and a second dopant, wherein the second doped semiconductor layer comprises the first dopant; wherein the first doped semiconductor layer is selectively formed on a first portion of a surface of the substrate; and, wherein the second doped semiconductor layer is selectively formed overlying the first doped semiconductor layer wherein a concentration of carbon is greater in the first doped semiconductor layer than in the second doped semiconductor layer.

2. The system of claim 1, wherein the controller is configured to perform a step of etching the first doped semiconductor layer and second doped semiconductor layer overlying the second surface in the one or more reaction chambers.

3. The system of claim 1, further comprising a substrate handling system.

4. The system of claim 3, further comprising a wall between the substrate handling system and the one or more reaction chambers.

5. The system of claim 1, further comprising a fourth gas source.

6. The system of claim 1, wherein the one or more reaction chambers comprise cross-flow, cold wall epitaxial reaction chamber.

7. The system of claim 1, comprising two or more reaction chambers, wherein the two or more reaction chambers are coupled to the controller.

8. The system of claim 1, wherein the first gas source comprises a chlorine-free precursor.

9. The system of claim 8, wherein the second gas source comprises a first dopant.

10. The system of claim 9, wherein the first dopant comprises a first p-type dopant.

11. The system of claim 9, wherein the third gas source comprises a second dopant.

12. The system of claim 11, wherein the second dopant comprises a second p-type dopant.

13. The system of claim 11, wherein the second dopant second dopant comprises gallium, aluminum, or indium.

14. The system of claim 13, wherein the first dopant comprises boron and the second dopant comprises gallium.

15. The system of claim 1, wherein the first doped semiconductor layer comprises p-type silicon germanium.

16. The system of claim 15, wherein the second doped semiconductor layer comprises p-type silicon germanium.

17. The system of claim 1, wherein the cap layer comprises at least one of silicon and germanium.

18. The system of claim 17, wherein the cap layer further comprises a p-type dopant selected from boron and gallium.

19. The system of claim 1, wherein the step of form the first doped semiconductor layer comprises providing a silicon precursor, a germanium precursor, a boron precursor, and a gallium precursor to the reaction chamber.
